(19) United States
(12) Patent Application Publication
(10) Pub. No.: US 2003/0220803 A1
(43) Pub. Date: Nov. 27, 2003

(54) Product replacement method and system

(76) Inventors: Todd Joseph Giaquinto, Cumberland, RI (US); Carl Joseph Meiser III, East Greenwich, RI (US)

Correspondence Address: Brett N. Dorny, Esq., Mintz, Levin, Cohn, Ferris,, Glovsky and Popeo, P.C., One Financial Center, Boston, MA, 02111, US

(21) Appl. No.: 10/153,298

(22) Filed: May 22, 2002

(51) Int. Cl. G06F 17/60; G01R 11/56

(52) U.S. Cl. 705/1; 705/412; 705/26

(57) ABSTRACT

A system for initiating a replacement or service request with respect to a expendable component, such as a battery in an uninterruptible power supply, includes a customer station, have the expendable component, and seller station to receive the replacement or service request. The customer station includes a computer which receives an indication that the expendable component needs replacement. The indication includes information about the expendable component necessary for replacement or service. The customer station communicates the information regarding the expendable component to the service station to initiate a replacement or service process. A method for operating the disclosed system to initiate the request is described.

### BACKGROUND OF THE INVENTION

1. Field of the Invention

The present invention relates to a system and method for monitoring consumable products at a remote location to determine appropriate replacement procedures. More particularly, it relates to a system and method for monitoring batteries of an uninterruptible power supply (UPS) at a customer location and for automated requests for replacement of batteries.

2. Discussion of Related Art

Uninterruptible power supplies are used to provide back up power to computer systems or other electrical equipment. UPS's include a battery as a power source and a inverter to convert DC battery power to AC power for use with the computer systems. While the system receives power from the utility, the battery is recharged. If power from the utility is lost, the UPS automatically switches to the backup battery power. Over time, performance of the battery degrades, such that it will no longer hold or receive a charge. Sometimes a battery is defective or becomes damaged. When the battery is no longer useful through degradation or damage, it needs to be replaced. Under current procedures, the user of the computer system attached to the UPS needs to determine when batteries have become defective and need replacement. In order to replace the battery, the user must locate information regarding model of the UPS and the particular batteries being used and contact information for the seller of the UPS. The user must then contact the seller, by telephone, electronic means or mail, in order to request and pay for a replacement battery.

More recently, smart UPSs, which have an internal microprocessor, have been able to monitor the performance of the UPS, including the batteries. The smart UPS communicates with the attached computer or computer system in order to inform the user of the performance of the UPS. In this manner, the smart UPS can inform the user when the batteries need to be replaced. However, the user still needs to retrieve information about the seller, the UPS, and the battery in order to request battery replacement.

The difficulties in obtaining the appropriate information to request battery replacement and transferring that information to the seller of replacement batteries can result in significant delays and errors. For example, the user may not obtain all of the necessary information to determine which battery is in a particular UPS and will have to go back to search for additional information after contacting the seller. Additionally, transcription errors by the user or the seller can result in erroneous information and shipping of an incorrect battery. There are often additional difficulties in contacting customer service personnel of a particular seller, including delays in locating the correct person, or in finding that person available. Furthermore, customer service personnel spend significant time entering information related to the battery and the customer to complete a replacement request.

Therefore, a need exists for a system which more efficiently collects and transfers information from the user to the seller regarding a particular battery that needs replacement. Additionally, similar difficulties in battery replacement occur with replacement or service requests related to other types of equipment. Therefore, a need exists for a system which can retrieve and transfer information relating to a request with respect to certain equipment in an efficient manner.

### SUMMARY OF INVENTION

The present invention substantially overcomes the deficiencies of the prior art by providing a system and method for automatically retrieving and transferring information from a user to a seller with respect to a battery replacement or a service request. According to one aspect of the invention, replacement or service requests are made electronically through a network, such as the Internet, connecting a customer computer with a seller computer. According to another aspect of the invention, the seller computer can prompt a user for all of the necessary information in order to complete an order for a replacement or service request. In particular, the system can adjust the requested information based upon prior information automatically provided by the system initiating a replacement or service request. According to another aspect of the invention, the user computer communicates with a smart UPS to determine automatically the necessary information for the battery replacement.

### BRIEF DESCRIPTION OF THE DRAWINGS

FIG. 1 is a block diagram representing the elements of a system for battery replacement according to an embodiment of the present invention.

FIG. 2 is a block flow diagram of a battery replacement method within the system illustrated in FIG. 1.

### DETAILED DESCRIPTION OF PREFERRED EMBODIMENTS

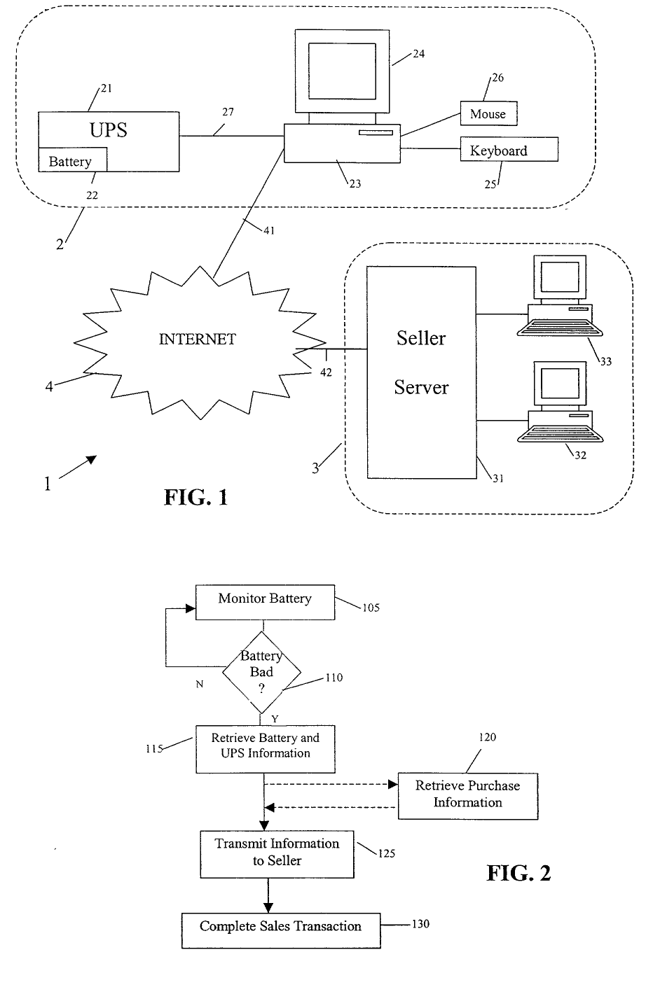

As illustrated in FIG. 1, the system 1 of the present invention includes a customer station 2, a seller station 3, and a network 4. The customer station 2 includes a UPS 21 and a customer computer 23. As illustrated, the customer computer 23 includes a monitor 24, a keyboard 25, and a mouse 26. Of course, the customer computer may be of any known type which allows communication with a network, and may include any type of input and output devices. The customer computer 23 is connected by a communication link 27 to the UPS 21. Of course, the UPS would also have a power connection to the customer computer, which is not shown.

As illustrated in FIG. 1, the seller location 3 includes a server 31 and one or more computers 32, 33, connected to the server 31. The customer computer 23 and the seller server 31 are connected through a network 4. Any known networking mechanism can be used for performing this connection. For example, the customer computer 23 can include a connection 41 to an internet service provider. Similarly, the seller server can include a connection 42 to the internet. Information can then be passed between the customer computer 23 and the seller server 31 through these internet connections. Alternatively, proprietary networks, intranets, extranets, or direct connections using modems over telephone lines can be made between the customer computer 23 and the seller server 31.

The system illustrated in FIG. 1 performs the method, as set forth in FIG. 2, in order to create a battery replacement request. At step 105, the condition of the battery is monitored. Software located at the customer computer 23 and on the UPS 21 operates jointly to perform this monitoring task. If the monitoring process determines if the battery is bad (step 110), a battery replacement request routine commences. A battery replacement request routine can occur automatically or through user intervention. For example, when a bad battery is determined to exist, the software on the user computer may provide a notification to the user of this condition. The notification may be done as a pop-up window on the monitor 24 of the customer computer 23. Alternatively, the software may send an e-mail to an electronic address identified by the user for such purposes. The notification may require the user to take some action to initiate the replacement request. For example, the user may click on a specific location or link in the pop-up window or e-mail. At step 115, the system retrieves battery and UPS information necessary for the replacement procedure. This information may be retrievable directly from the UPS through the communications link 27. Alternatively, the user may be required to look up and enter additional information in order to complete the request. Similarly, at step 120, additional information may need to be retrieved in order to complete the purchase of the replacement battery. For example, the user may be required to input appropriate contact information or financial information necessary to complete the purchase or request. At step 125, the information retrieved at the user computer 23 is transmitted to the seller. Various mechanisms can be used to perform this transmission. According to a preferred embodiment, the software at the customer computer 23 generates a HTPP POST or GET request to the seller server through the network 4, the POST or GET request includes a data packet with information regarding the UPS, battery, and/or customer. The HTPP POST or GET request may be generated in response to the user selecting a link in the pop-up window or e-mail. A software application at the seller server 31 monitors and extracts data packets received through the HTPP protocol. The decoded data packet is analyzed to determine whether it includes the information related to bad batteries. If one or more devices are identified in the data packets as having bad batteries, the software at the seller server 31 transmits back a page to be displayed at the customer computer related to the battery replacement process. The user then has the option to submit contact information in order to initiate a service or replacement request. Different pages can be used and displayed to the user depending upon the specific products or batteries connected to the customer computer 23. The correct service page can be determined upon decoding of the data packet with information relating to the battery and UPS. Alternatively, software in the customer computer 23 can include processes for retrieving all of the necessary customer information prior to sending the HTTP POST or GET request. In this manner, the data packet is processed at one time by the seller server 31.

Once all of the necessary information has been received from the customer computer 23, the seller server 31 transmits the information to an appropriate attached computer 32, 33. For example, the seller server 31 may transfer information to a shipping department computer to cause replacement batteries to be shipped to the customer. Similarly, the information may be transferred to a financial services computer in order to charge the customer for the replacement batteries. Alternatively, the information can be transferred to an appropriate service representative for that customer in order to arrange for a service visit to replace the batteries. The steps necessary to complete the sales transaction (step 130) are dependent upon the nature of the product being replaced and procedures of the seller.

The present invention has been illustrated with respect to replacement of batteries in a UPS. However, the invention is not limited to this use. A similar system and method can be used to monitor and request replacement of any consumable or defective device, such as ink in a printer or defective peripherals such as hard drives, tape drives, etc.

Furthermore, the present invention is not limited to replacement of a single part of a UPS or other peripheral. A computing environment may include a variety of peripherals connected to a single computer. Similarly, a large number of UPS's could be connected to a single computer for monitoring purposes. Alternatively, computers on a network may communicate information regarding the status of individual UPS's to a single computer which performs network monitoring functions. In all of these configurations, a single computer communicates with multiple devices. The system of the present invention can be used for replacement of multiple components within such configurations. For example, when a single computer monitors a large number of UPSs, that computer can operate to order a number of batteries for replacement. The operation of the system, as illustrated in FIG. 2, does not change. The only modifications are that steps 105 and 110 monitor a plurality of batteries and the information for a plurality of batteries are retrieved as step 115 and transmitted to the seller at step 125.

Having thus far described at least one illustrative embodiment of the invention, various alterations, modifications and improvements will readily occur to those skilled in the art. Such alterations, modifications and improvements are intended to be within the scope and spirit of the invention. Accordingly, the foregoing description is by way of example only and is not intended as limiting. Accordingly, the invention is defined by the following claims and equivalents thereof.

What is claimed is:

1. A method for ordering a component of a uninterruptible power supply for replacement, the uninterruptible power supply being connected for communication to a customer computer, the method comprising the steps of:
transferring from the uninterruptible power supply to the customer computer information regarding the component for replacement;
communicating the information regarding the component for replacement from the computer to a seller computer; and
preparing an order for the component at a seller location based upon the information communicated to the seller computer.

2. The method for ordering a component for replacement according to claim 1, wherein component for replacement is a battery in the uninterruptible power supply.

3. The method for ordering a component for replacement according to claim 1, wherein the information regarding the component includes information identifying the uninterruptible power supplies and information identifying the component.

4. The method for ordering a component for replacement according to claim 1, wherein the step of communicating the information includes the steps of:
communicating the information from the consumer computer to a network;
communicating the information from the network to a seller server; and
communicating the information from the seller server to the seller computer.

5. The method for ordering a component for replacement according to claim 1, wherein the step of communicating the information includes the steps of:
notifying a user of the consumer computer that a replacement is necessary;
receiving an indication from the user that an order should be created; and
communicating the information regarding the component for replacement from the consumer computer to the seller computer after receiving the indication from the user that an order should be created.

6. The method for ordering a component for replacement according to claim 5, wherein the step of communicating the information further includes the steps of:
requesting customer information from the user; and
communicating the customer information from the customer computer to the seller computer.

7. The method for ordering a component for replacement according to claim 6, wherein the customer information includes financial information.

8. The method for ordering a component for replacement according to claim 1, wherein the step of preparing an order includes the steps of:
communicating a request for customer information from the seller computer to the customer computer upon receipt of the information regarding the component; and
communicating customer information from the customer computer to the seller computer in response to the request.

9. A component replacement ordering system, comprising:
a customer computer receiving information regarding at least one component needing replacement;
a seller computer preparing an order for the at least one component upon receipt of information regarding the at least one component needing replacement; and
a communication network connecting the customer computer and the seller computer for communicating the information regarding at least one component needing replacement from the customer computer to the seller computer.

10. The component replacement ordering system of claim 9, further comprising:
an uninterruptible power supply, including the at least one component as at least a part, communicating with the customer computer to transmit the information regarding the at least one component needing replacement.

11. The component replacement ordering system of claim 10, wherein the component is a battery in the uninterruptible power supply.

12. The component replacement ordering system of claim 9, further comprising:
means at the customer computer for informing a user that the at least one component needs replacement;
an input at the customer computer for receiving an indication from the user that an order should be created; and
means for communicating the information regarding the at least one component needing replacement through the communication network in response to receipt of the indication that an order should be created.

13. The component replacement ordering system of claim 9, further comprising:
means at the seller computer for communicating a request for customer information to the customer computer upon receipt of the information regarding at least one component needing replacement; and
means at the customer computer for communicating customer information to the seller computer upon receipt of the request for customer information.

14. The component replacement ordering system of claim 13, wherein the customer information includes financial information.

15. A method for ordering a plurality of components for replacement, the plurality of components relating to a plurality of uninterruptible power supplies, each of the plurality of uninterruptible power supplies being connected for communication to a customer computer, the method comprising the steps of:
transferring from the plurality of uninterruptible power supplies to the customer computer information regarding the plurality of components for replacement;
communicating the information regarding the plurality of components for replacement from the computer to a seller computer; and
preparing an order for the plurality of components at a seller location based upon the information communicated to the seller computer.

16. The method for ordering a plurality of components for replacement according to claim 15, wherein the information regarding the plurality of components includes information identifying each uninterruptible power supply in the plurality of uninterruptible power supplies and corresponding information identifying a component for replacement in the plurality of components.
